(19) United States
(12) Patent Application Publication
(10) Pub. No.: US 2007/0187688 A1
(43) Pub. Date: Aug. 16, 2007

(54) Co-planar thin film transistor having additional source/drain insulation layer

(75) Inventors: Kenneth R. Whight, Horsham (GB); Ian French, Hove (GB)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/568,460

(22) PCT Filed: Apr. 26, 2005
(86) PCT No.: PCT/IB05/51358

§ 371 Date: Oct. 30, 2006

(30) Foreign Application Priority Data
Apr. 28, 2004 (GB) 0409439.7

(51) Int. Cl. H01L 29/04

(52) U.S. Cl. 257/72

(57) ABSTRACT

A co-planar thin film transistor, TFT (22), and a method of fabricating the same, in which an additional insulating layer is provided on the source contact (30) and the drain contact (32) and defined such that a first region (34) of the additional insulating layer occupies substantially the same area as the source contact (30) and a second region (36) of the additional insulating layer occupies substantially the same area as the drain contact (32). This tends to provide a reduction in the gate (62) to source capacitance, and the gate (62) to drain capacitance. In some geometries this can be achieved without any additional masks or defining steps.

The present invention relates to thin film transistors, in particular co-planar thin film transistors, and methods of fabricating such transistors.

In a co-planar thin film transistor (TFT), the source, drain and gate metallisation are all provided on the same side of a thin film semiconductor layer.

In conventional co-planar TFTs, there is only a relatively thin insulator layer between the gate metallisation and the source metallisation, and likewise between the gate metallisation and the drain metallisation, since this insulator layer is also provided between the gate electrode and the semiconductor material, and excessive thickness of this layer would therefore degrade the TFT performance. As a result, conventional co-planar TFTs typically have a higher effective gate to source capacitance and gate to drain capacitance than bottom gate TFTs and top gate TFTs.

One particularly promising use of co-planar TFTs is as a current control, i.e. drive, TFT in active matrix polymer light emitting diode (AMPLED) displays, devices. Such a display device is described in US 2003/0098828. Typically, co-planar TFTs based on polysilicon are employed, as the polysilicon has a low reverse leakage and is electrically stable allowing an accurate current to be supplied through the LED for a given gate voltage applied to the TFT.

In a first aspect, the present invention provides a co-planar thin film transistor, TFT, comprising: a channel region, a source contact and a drain contact formed on a substrate from a plurality of semiconductor layers and a first metal layer; a first insulating layer provided on the source contact and the drain contact and defined such that a first region of the first insulating layer occupies substantially the same area as the source contact and a second region of the first insulating layer occupies substantially the same area the drain contact; a second insulating layer provided on the channel region and the first and second regions of the first insulating layer; and a second metal layer provided on the second insulating layer and defined so as to provide a gate.

The first insulating layer may comprise insulating material and contact holes; in this case the first region of the first insulating layer occupies substantially the same area as the source contact and the second region of the first insulating layer occupies substantially the same area as the drain contact by virtue of some of the area of the source contact and the drain contact being occupied by the insulating material of the first insulating layer, and some of the area of the source contact and the drain contact being occupied by the contact holes in the first insulating layer.

The plurality of semiconductor layers may comprise an undoped μ-Si layer.

The plurality of semiconductor layers may comprise an n+ a-Si layer providing a source and drain.

In a further aspect, the present invention provides an active matrix display device comprising thin film transistors according to any of the above versions of the first aspect described above.

In a further aspect, the present invention provides a method of forming a co-planar thin film transistor, TFT, comprising the steps of forming on a substrate: a channel region; a source; a drain; a source contact; a drain contact; a first region of a first insulating layer on, and occupying substantially the same area as, the source contact; a second region of the first insulating layer on, and occupying substantially the same area as, the drain contact; a second insulating layer on the channel region and the first and second regions of the first insulating layer; and a gate on the second insulating layer.

The first and second regions of the first insulating layer may have contact holes therein allowing contact with the source contact and drain contact.

The TFT may be formed with a first semiconductor layer comprising undoped μ-Si.

The TFT may be formed with a second semiconductor layer comprising n+ a-Si.

The first insulating layer, more particularly the first and second regions of the first insulating layer, are in effect additional insulating layer regions compared to the insulating layer present in conventional co-planar TFTs. The first and second regions of this additional first insulating layer tend to provide a reduction in the gate to source capacitance, and the gate to drain capacitance, of the TFT. In some geometries this can be achieved without any additional masks or defining steps.

In a further aspect, the above described co-planar TFT is fabricated on the same substrate, and with some shared process steps, as an a-Si TFT of different geometry. Even in this case, only one additional mask may be required to provide the benefits of the first and second regions of the first insulating layer.

The first and second regions of the first insulating layer may be considered as being padding dielectric layers. As such, according to the present invention, padding dielectric layer regions are provided over the source and drain contacts of a co-planar TFT.

The padding dielectric layer regions tend to provide increased insulation between the gate and source, and between the gate and drain, respectively, i.e. they provide a reduction in the gate to source capacitance, and gate to drain capacitance. In some aspects of the invention, the padding dielectric layer regions provide this increased insulation, i.e. decreased capacitance, in the direction substantially perpendicular to the substrate, in other words in the substantially “vertical” direction if the substrate is considered as being in the “horizontal” plane, or in yet further words, in the direction in which the layers are deposited and built-up, as opposed to in the direction of the plane of the substrate. In further aspects of the invention, the padding dielectric layer regions may additionally provide increased insulation between the gate and the source and the gate and the drain, i.e. decreased capacitance between the gate and the source and the gate and the drain, in directions away from the plane of the substrate other than substantially perpendicular to the substrate, e.g. at 45° to the plane of the substrate. In yet further aspects of the invention, the padding dielectric regions may provide increased insulation between the gate and the source and the gate and the drain, i.e. decreased capacitance between the gate and the source and the gate and the drain, in directions away from the plane of the substrate other than substantially perpendicular to the substrate, e.g. at 45° to the plane of the substrate, without necessarily providing such decreased capacitance in the direction substantially perpendicular to the substrate.

More generally it will be appreciated that the padding dielectric regions may tend to provide increased insulation, i.e. decreased capacitance, in any directions and locations where the source and/or drain contacts overlap and/or are in relatively close proximity to the gate metal.

Embodiments of the present invention will now be described, by way of example, with reference to the accompanying drawings, in which:

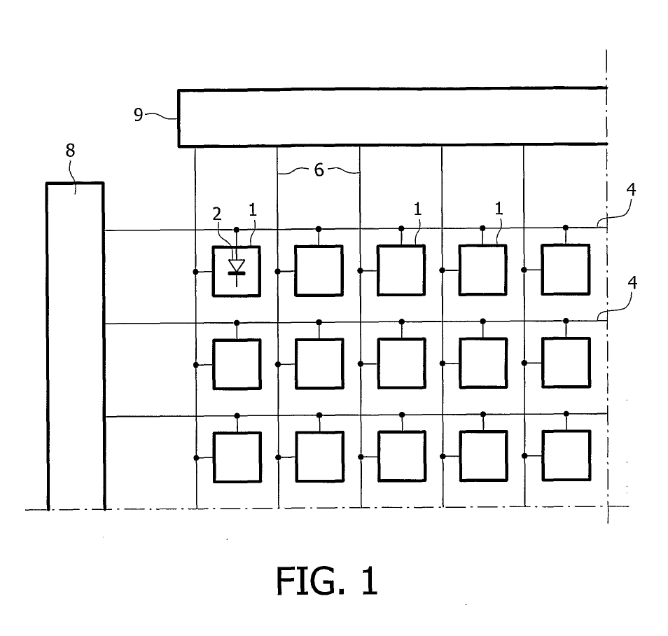

FIG. 1 is a schematic illustration of part of an active matrix addressed colour electroluminescent display device comprising TFTs;

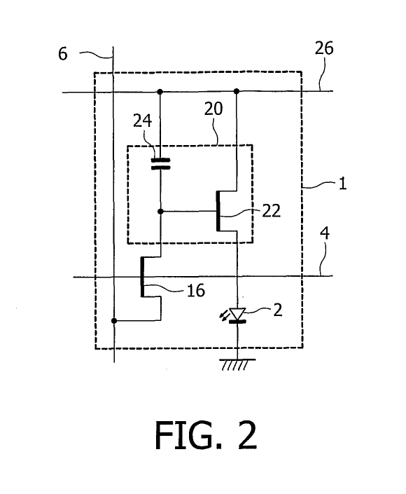

FIG. 2 shows in simplified schematic form a pixel and drive circuitry arrangement used for each pixel of the display device of FIG. 1;

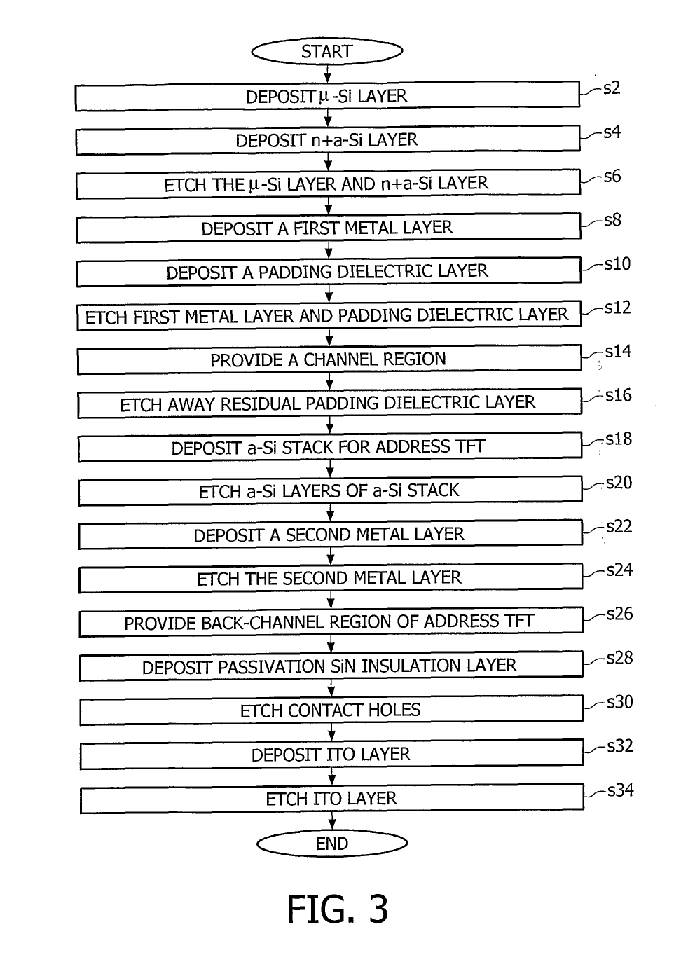

FIG. 3 is a flowchart showing process steps employed in a process of producing TFTs of the display device of FIG. 1; and

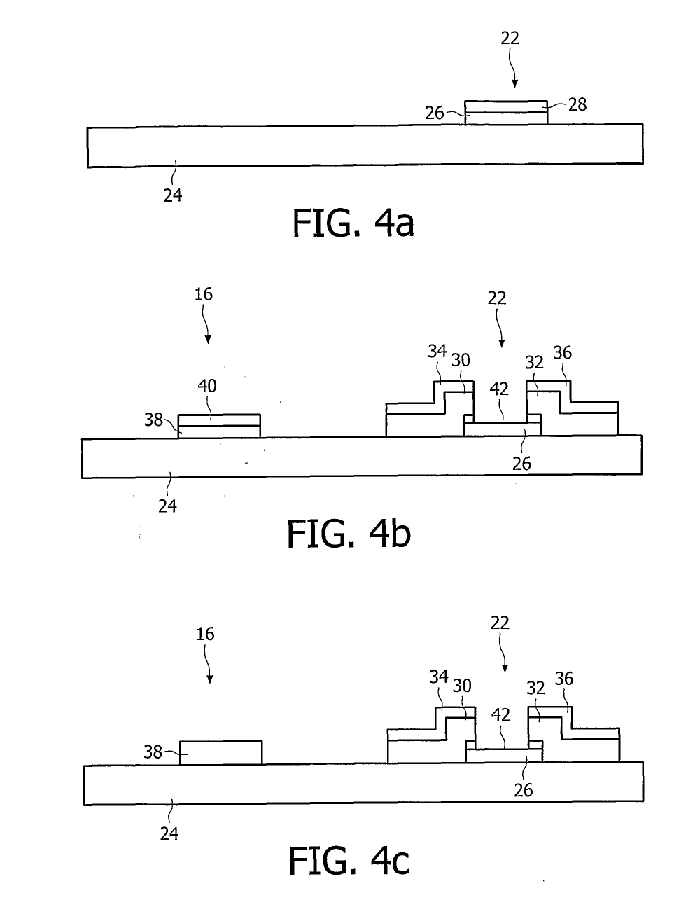

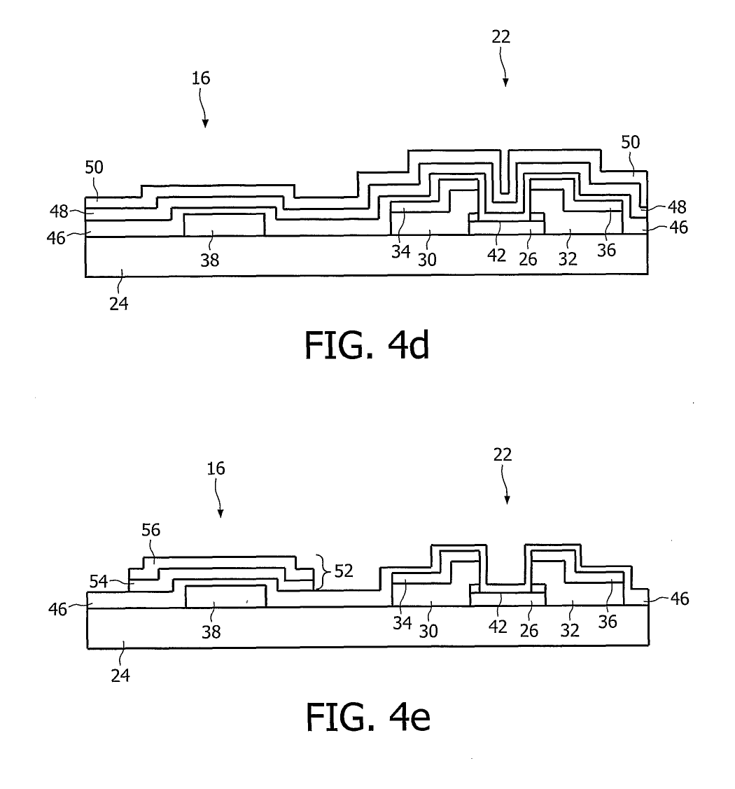

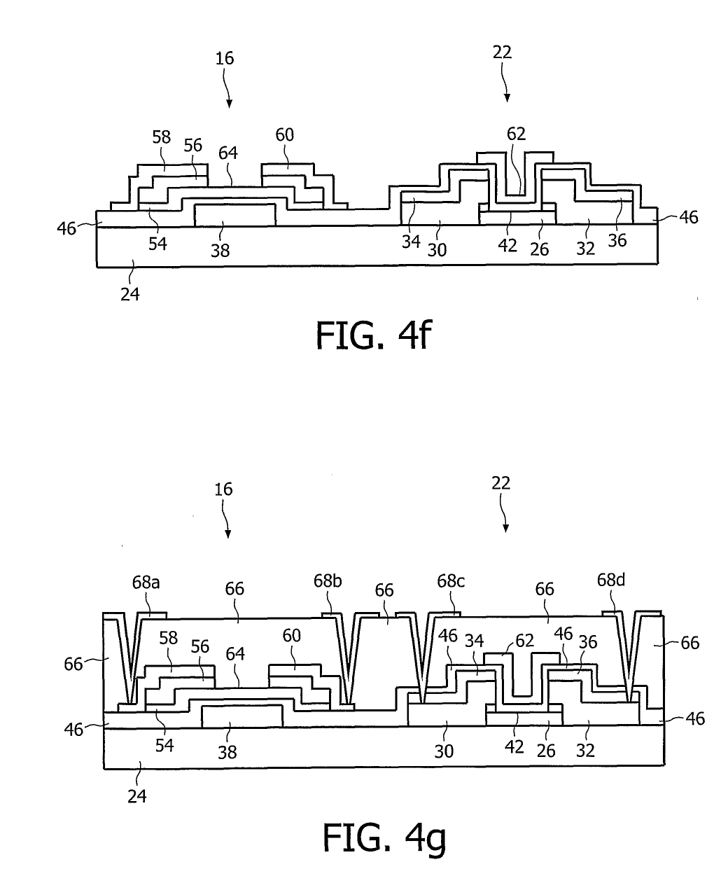

FIGS. 4a-4g schematically illustrate the build-up of various layers on a substrate as the process of FIG. 3 progresses.

The first embodiment described below is for a TFT arrangement as used in an AMPLED display device. Nevertheless, it is to be appreciated that in other embodiments the same or corresponding TFT structures may be provided for different uses, and indeed both the TFT structure and the process of manufacturing the TFT represent embodiments of the invention in themselves.

FIG. 1 is a schematic illustration of part of an active matrix addressed colour electroluminescent display device comprising TFTs according to the first embodiment. The active matrix addressed electroluminescent display device comprises a panel having a row and column matrix array of regularly-spaced pixels, denoted by the blocks 1 and comprising electroluminescent display elements 2 together with associated switching means. The pixels 1 are located at the intersections between crossing sets of row (selection) and column (data) address conductors 4 and 6. Only a few pixels 1 are shown in the Figure for simplicity. In practice there may be several hundred rows and columns of pixels 1. The pixels 1 are addressed via the sets of row and column address conductors by a peripheral drive circuit comprising a row, scanning, driver circuit 8 and a column, data, driver circuit 9 connected to the ends of the respective sets of conductors.

The electroluminescent display element 2 comprises an organic light emitting diode, represented here as a diode element (LED) and comprising a pair of electrodes between which one or more active layers of organic electroluminescent material is sandwiched. The display elements of the array are carried together with the associated active matrix circuitry on one side of an insulating support. Either the cathodes or the anodes of the display elements are formed of transparent conductive material. The support is of transparent material such as glass and the electrodes of the display elements 2 closest to the substrate may consist of a transparent conductive material such as ITO so that light generated by the electroluminescent layer is transmitted through these electrodes and the support so as to be visible to a viewer at the other side of the support. Typically, the thickness of the organic electroluminescent material layer is between 100 nm and 200 nm.

Typical examples of suitable organic electroluminescent materials which can be used for the elements 2 are known and described in EP-A-O 717446. Conjugated polymer materials as described in WO96/36959 can also be used.

FIG. 2 shows in simplified schematic form a pixel and drive circuitry arrangement used for each pixel 1 in this embodiment. Each pixel 1 comprises the EL display element 2 and associated driver circuitry. The driver circuitry has an address transistor 16 which is turned on by a row address pulse on the row conductor 4. When the address transistor 16 is turned on, a voltage on the column conductor 6 can pass to the remainder of the pixel. In particular, the address transistor 16 supplies the column conductor voltage to a current source 20, which comprises a drive transistor 22 and a storage capacitor 24. The column voltage is provided to the gate of the drive transistor 22, and the gate is held at this voltage by the storage capacitor 24 even after the row address pulse has ended.

The pixel and drive circuitry arrangement is operated in an analogue mode. The range of the gate voltages on the drive transistor 22 in combination with the voltage on the power rail 26 supplying the current source 20 are selected such that the transistor is operating in the linear region, so that the source-drain current is approximately linearly proportional to the gate voltage. Thus, the voltage on the column conductor 6 is used to select a desired current flow to the display element 2. Typically around 6V will be dropped across the source-drain of the drive transistor 22, and as a result, the voltage on the power rail 26 will need to be around 10V so that a required voltage drop across the LED of around 4V is achieved (when the cathode is grounded as shown). Typical gate voltages will be in a range with a stored voltage on the storage capacitor 24 of around 4V. For example, the data signal on the column conductor 6 may fall within a range of around 5-7V.

In this active matrix addressed colour electroluminescent display device, the drive transistor 22 and the address transistor 16 are in detail of different respective TFT technologies but nevertheless are fabricated during a common overall multilayer process on the same substrate. In essence, the main semiconductor layer of the drive transistor 22 comprises microcrystalline silicon (μ-Si) deposited by one form of plasma enhanced chemical vapour deposition (PECVD) process, whereas the main address transistor 16 comprises amorphous silicon (a-Si) deposited by another form of (PECVD) process.

The address transistor 16 needs to have a low reverse leakage for its switching role. The drive transistor 22 needs to have high electrical stability, so that the current supplied to the EL display element 2 is an accurate reflection of the signal voltage applied to the gate of the drive transistor 22.

Generally it is preferred to fabricate TFTs from a-Si as this is a relatively simple and cost effective fabrication technology. However, although a-Si TFTs have low reverse leakage, they do not have high electrical stability, and therefore cannot be used for both the address transistor 16 and the drive transistor 22. Thus, usually for AMPLED display devices, TFTs are fabricated using polysilicon technology, as the resulting TFTs have both low reverse leakage and high electrical stability. Polysilicon technology is however less simple and cost effective than a-Si technology.

In the present example, the drive transistor 22 is fabricated using PECVD deposited μ-Si, as this process provides TFTs with high electrical stability as required by the drive transistor 22. Such TFTs do not have low 20 reverse leakage, but this does not matter for the drive transistor 22. This is advantageous because the PECVD μ-Si deposition process is relatively simple and cost effective. Moreover, the PECVD μ-Si deposition process is similar to the a-Si fabrication process, and hence is used here advantageously by carrying out both processes on the same substrate in one overall combined process to fabricate the address transistor 16 with a-Si and the drive transistor with μ-Si. This combines the benefit of simple and cost effective process for both transistor types, whilst each transistor type achieves the required strong characteristic of the respective technology.

Combining the two technologies of a-Si and μ-Si in the above described manner will require additional masking steps compared to the use of either technology in isolation, which adds to the complexity and cost of the fabrication process. The number of additional masks required will depend on the respective geometries chosen for the two transistors, e.g. whether top-gate, bottom-gate or co-planar. In this example the a-Si address transistor 16 is bottom-gate, and the μ-Si drive transistor 22 is co-planar, this combination advantageously requires just one additional masking step.

In the arrangement described below, the co-planar μ-Si drive transistor 22 is provided with padding dielectric layer regions over the source and drain contacts, thereby alleviating the characteristic typically found in conventional co-planar TFTs of having relatively high gate to source capacitance and gate to drain capacitance.

FIG. 3 shows the process steps employed in this embodiment for producing the address transistor 16 and the drive transistor 22. These process steps will now be described, with the aid of FIGS. 4a-4g which schematically illustrate the build-up of various layers on a substrate 24 as the process progresses. FIGS. 4a-4g show the build up of the layers in cross-section for one address transistor 16 and one drive transistor 22, i.e. for one pixel 1. It will be appreciated however, that the procedures described below in relation to a single pixel 1 are in fact performed at the same time for the whole array of pixels.

The features shown in FIG. 4a are formed as follows. At step s2, a microcrystalline silicon (μ-Si) layer is deposited on the substrate 24. At step s4, an n+ amorphous silicon (a-Si) layer is deposited on the μ-Si layer. At step s6, the μ-Si layer and the n+ a-Si layer are etched, using a first mask, to define a μ-Si TFT region, i.e. at this stage a μ-Si TFT region 26 and an intermediate n+ a-Si region 28 are provided, as shown in FIG. 4a. These structures will form part of the drive transistor 22.

The additional features shown in FIG. 4b are formed as follows. At step s8, a first metal layer is deposited over the substrate 24 including over the intermediate n+ a-Si region 28. At step s10, a dielectric layer, i.e. insulating layer, hereinafter referred to as a padding dielectric layer, is deposited over the first metal layer. In this embodiment, this padding dielectric layer is of SiN. However, in other embodiments, this padding dielectric layer may be of any suitable low dielectric constant material. At step s12, the first metal layer and the padding dielectric layer are etched, using a second mask, to define elements for both the drive transistor 22 and the address transistor 16.

The elements defined for the drive transistor 22 are a source contact 30 and a drain contact 32 formed from the first metal layer and located over respective parts of the intermediate n+ a-Si region 28; and a source padding dielectric layer region 34 and a drain padding dielectric layer region 36. As the metal layer and the dielectric padding layer are etched with the same mask, the source padding dielectric layer region 34 is directly on top of, and occupies the corresponding substrate area as the source contact 30 of the drive transistor 22. Likewise, the drain padding dielectric layer region 36 is directly on top of, and occupies the corresponding substrate area, as the drain contact 32 of the drive transistor 22. Thus the source contact 30 of the drive transistor 22 is covered by the source padding dielectric layer region 34; likewise the drain contact 32 of the drive transistor 22 is covered by the drain padding dielectric layer region 36.

The elements defined for the address transistor 16 are a gate 38, i.e. the gate metal, which is defined by the etching from the first metal layer, and a residual padding dielectric layer region 40 directly on top of, and occupying the corresponding substrate area as the newly defined gate 38 of the address transistor 16.

At step s14, the intermediate n+ a-Si region 28 is etched away between the source contact 30 and the drain contact 32 of the drive transistor 22, thereby providing a channel region 42 of the drive transistor 22.

Referring to FIG. 4c, at step s16, the residual padding dielectric layer region 40 is etched away using a third mask, thus again exposing the metal gate region 38 of the address transistor 16. As the whole of the residual padding dielectric layer region 40 is being etched away, as opposed to being patterned, this mask is non-critical in terms of definition or resolution. Thus, for example, a printing or inkjet definition process may be employed, as is the case in this embodiment, instead of a more onerous photolithography process. Also, note that in embodiments where only a transistor corresponding to the drive transistor is being fabricated, i.e. not with a further transistor corresponding to the address transistor 16, then neither step 16 nor the third mask is required.

The additional features shown in FIG. 4d are formed as follows. At step s18 an a-Si TFT stack 44 for the address transistor 16 is deposited over the structure shown in FIG. 4c. The a-Si TFT stack 44 comprises, in order of deposition, a SiN insulating (passivation) layer 46, an undoped a-Si layer 48, and an n+ doped a-Si layer 50. Note in the area of the drive transistor 22, the SiN insulating (passivation) layer will provides the conventional insulation between the gate metal and, respectively, the source and drain contacts.

The additional features shown in FIG. 4e are formed as follows. At step s20, the a-Si layer 48 and the n+ a-Si layer 50 of the a-Si stack 44 are etched using a fourth mask, thereby defining an a-Si island 52 of the address transistor extending over and beyond the area of the metal gate region 38. The a-Si island 52 comprises an undoped a-Si island region 54 covered by an n+ a-Si island region 56. During the etching step s20, the a-Si layer 48 and the n+ a-Si layer 50 of the a-Si stack 44 are etched away from other areas, in particular away from the area of the drive transistor 22.

The additional features shown in FIG. 4f are formed as follows. At step s22, a second metal layer is deposited over the structure shown in FIG. 4e. At step s 24, the second metal layer is etched, using a fifth mask, to define a source contact 58 and a drain contact 60 for the address transistor 16, and a gate 62 for the drive transistor 22. At step s26, the n+ a-Si layer 50 between the source contact 58 and the drain contact 60 of the address transistor 16 is etched away between the source contact 58 and the drain contact 58 of the address transistor 16, thereby providing a back-channel region 64 of the address transistor 16.

The additional features shown in FIG. 4g are formed as follows. At step s28 a passivation SiN insulating layer 66 is deposited over the structure shown in FIG. 4f. At step s30, contact holes are etched, using a sixth mask, through the various layers to required contact points on the first and second metal layers as appropriate. At step s32, an indium tin oxide (ITO) transparent conductive layer is deposited over the structure which now includes the contact holes formed at step s30. At step s34, the ITO layer is etched, using a seventh mask, to form interconnects 68 to the various metal layers. In FIG. 4g, for clarity, only some of the required interconnects 68 are shown, namely a source interconnect 68a and a drain interconnect 68b contact for the address transistor 16, and a source interconnect 68c and a drain interconnect 68d for the drive transistor 22. This represents a simple connection process, i.e. a further advantage pf the present embodiment is that the padding dielectric regions are provided without the need for introducing complex connection requirements.

The source interconnect 68c of the drive transistor 22 passes though the source padding dielectric layer region 34 in order to reach the source contact 30 of the drive transistor 22. Other than this, the source padding dielectric layer region 34 remains over the source contact 30 of the drive transistor 22, and the area of the source padding dielectric layer region 34 corresponds to the area of the source contact 30 of the drive transistor 22.

Likewise, the drain interconnect 68d of the drive transistor 22 passes though the drain padding dielectric layer region 36 in order to reach the drain contact 32 of the drive transistor 22. Other than this, the drain padding dielectric layer region 36 remains over the drain contact 32 of the drive transistor 22, and the area of the drain padding dielectric layer region 36 corresponds to the area of the drain contact 32 of the drive transistor 22.

Thus, the co-planar drive transistor 22, comprising the source padding dielectric layer region 34 and the drain padding dielectric layer region 36, is an embodiment of a TFT according to the present invention.

The source padding dielectric layer region 34 and the drain padding dielectric layer region 36 provide increased insulation between the gate and source, and between the gate and drain, respectively, i.e. they provide a decrease in the gate to source capacitance, and gate to drain capacitance, respectively. In this embodiment, the source padding dielectric layer region 34 and the drain padding dielectric layer region 36 provide this increased insulation, i.e. decreased capacitance, in the direction substantially perpendicular to the substrate 24, in other words in the substantially “vertical” direction if the substrate is considered as being in the “horizontal” plane, or in yet further words, in the direction in which the layers are deposited and built-up, as opposed to in the direction of the plane of the substrate.

In other embodiments, as a consequence of the respective positions of the source metal, the drain metal, and the gate metal, the padding dielectric regions provided according to the invention may be positioned such as to additionally provide increased insulation between the gate and the source and the gate and the drain, i.e. decreased capacitance between the gate and the source and the gate and the drain, in directions away from the plane of the substrate other than substantially perpendicular to the substrate, e.g. at 45° to the plane of the substrate. In yet further geometries, the padding dielectric regions provided according to the invention may be positioned such as to provide increased insulation between the gate and the source and the gate and the drain, i.e. decreased capacitance between the gate and the source and the gate and the drain, in directions away from the plane of the substrate other than substantially perpendicular to the substrate, e.g. at 45° to the plane of the substrate, without necessarily providing such decreased capacitance in the direction substantially perpendicular to the substrate.

More generally it will be appreciated that the padding dielectric regions tend to provide increased insulation, i.e. decreased capacitance, in any directions and locations where the source and/or drain metal overlaps and/or is in relatively close proximity to the gate metal.

In the above described embodiment, the transistors with the padding dielectric regions provided therein (the drive transistors 22) are fabricated during a process that also fabricates other transistors (the address transistors 16). As a consequence of this, one additional mask stage is required to accommodate the presence of the padding dielectric regions (step s16, i.e. the third mask, in the above described embodiment). In other embodiments, only transistors with padding dielectric regions provided therein are fabricated. In this case, there is no requirement for the additional mask stage (i.e. step s16 using the third mask in the above described embodiment may be omitted), i.e. the padding dielectric regions of the present invention may advantageously be provided in such embodiments without the need of any additional mask stages compared to conventional co-planar TFT fabrication processes.

In the above described embodiment, the AMPLED display device is bottom-emitting, hence the interconnects are deposited as ITO. In the case of top-emitting displays, the interconnects may be formed of metal in conjunction with the ITO.

In the above described embodiment, the TFT to which the padding dielectric regions are added are drive transistors 22 of an AMPLED display device. However, in other embodiments the TFTs may be for other types of display device, or more generally the present invention may be applied to any other co-planar TFTs, whether for display devices or for other applications, whose geometry allows the introduction of padding dielectric regions along the lines outlined above.

In the above described embodiment, the undoped semiconductor material of the co-planar TFT for which the padding dielectric regions are provided is μ-Si. However, in other embodiments, other undoped semiconductor material may be used, e.g. a-Si.

In the above described embodiment, the padding dielectric regions are made of SiN. However, in other embodiments, any other suitable insulator material may be used. Moreover, in the above described embodiment, the passivation layer adjoining the padding dielectric regions (SiN layer 46), which is the insulation thickness to which the insulation provided by the padding dielectric regions is effectively added to improve the total insulation, is also made of SiN, i.e. the conventional insulation layer and the added padding dielectric regions are of the same material. However, this need not be the case, and in other embodiments these may be of differing materials.

1. A co-planar thin film transistor, TFT, comprising:
a substrate (24);
a plurality of semiconductor layers (26, 28) and a first metal layer deposited on the substrate (24) and defined to provide a channel region (42), a source contact (30) and a drain contact (32);
a first insulating layer provided on the source contact (30) and the drain contact (32) and defined such that a first region of the first insulating layer (34) occupies substantially the same area as the source contact (30) and a second region of the first insulating layer (36) occupies substantially the same area as the drain contact (32);
a second insulating layer (46) provided on the channel region (42) and the first (34) and second (36) regions of the first insulating layer; and
a second metal layer provided on the second insulating layer (46) and defined so as to provide a gate (62).

2. A co-planar TFT according to claim 1, wherein the first insulating layer comprises insulating material and contact holes; and the first region of the first insulating layer (34) occupies substantially the same area as the source contact (30) and the second region of the first insulating layer (36) occupies substantially the same area as the drain contact (32) by virtue of some of the area of the source contact (30) and the drain contact (32) being occupied by the insulating material of the first insulating layer and some of the area of the source contact (30) and the drain contact (32) being occupied by the contact holes in the first insulating layer.

3. A co-planar TFT according to claim 1, wherein the plurality of semiconductor layers comprises an undoped μ-Si layer (26).

4. A co-planar TFT according to claim 1, wherein the plurality of semiconductor layers comprises an n+ a-Si layer (28) providing a source and drain.

5. An active matrix display device comprising thin film transistors according to claim 1.

6. A method of forming a co-planar thin film transistor, TFT, comprising the steps of:
depositing, and defining, a plurality of semiconductor layers (26, 28), a first metal layer and a first insulating layer, on a substrate (24);
the defining being performed so as to form:
a channel region (42) in a first semiconductor layer (26) of the plurality of semiconductor layers;
a source and a drain;
a source contact (30) and a drain contact (32) from the first metal layer;
a first region of the first insulating layer (34) provided on, and occupying substantially the same area as, the source contact (30);
a second region of the first insulating layer (36) provided on, and occupying substantially the same area as, the drain contact (32);
depositing a second insulating layer (46) on the channel region (42) and the first (34) and second (36) regions of the first insulating layer; and
depositing and defining a second metal layer on the second insulating layer (46) so as to form a gate (62).

7. A method of forming a co-planar TFT according to claim 6, wherein the first metal layer and the first insulating layer are defined using the same mask.

8. A method of forming a co-planar TFT according to claim 6, further comprising forming contact holes in the first insulating layer.

9. A method of forming a co-planar TFT according to claim 6, wherein the first semiconductor layer comprises an undoped μ-Si layer (26).

10. A method of forming a co-planar TFT according to claim 6, wherein a second layer of the plurality of semiconductor layers comprises n+ a-Si (28), which is defined to provide the source and the drain.
